(19) United States
(12) Patent Application Publication
(10) Pub. No.: US 2026/0114190 A1
(43) Pub. Date: Apr. 23, 2026

(54) MEMORY ELEMENT FOR IMPLEMENTING MULTI-LEVEL AND MEMORY DEVICE COMPRISING THE SAME

(71) Applicant: KOREA UNIVERSITY RESEARCH AND BUSINESS FOUNDATION, Seoul (KR)

(72) Inventors: Taegeun KIM, Seongnam-si (KR); Jongmin JOO, Seoul (KR)

(73) Assignee: KOREA UNIVERSITY RESEARCH AND BUSINESS FOUNDATION, Seoul (KR)

(21) Appl. No.: 19/352,943

(22) Filed: Oct. 8, 2025

(30) Foreign Application Priority Data
Oct. 22, 2024 (KR) 10-2024-0144774

(51) Int. Cl. H10N 70/00; G11C 13/00; H10B 63/10; H10N 70/20

(52) U.S. Cl. CPC H10N 70/882; H10B 63/10; H10N 70/231; H10N 70/8413; G11C 13/004

(57) ABSTRACT

The memory element may include a lower electrode that includes a heater, a stacked structure that is stacked on the lower electrode and includes a first chalcogenide layer that includes a first chalcogenide material, a second chalcogenide layer that includes a second chalcogenide material, and a first anti-mixing layer that prevents diffusion between the first chalcogenide layer and the second chalcogenide layer, and an upper electrode that is stacked on the stacked structure, wherein the first chalcogenide layer may be stacked on the lower electrode, the first anti-mixing layer may be stacked on the first chalcogenide layer, the second chalcogenide layer may be stacked on the first anti-mixing layer, and a first threshold voltage that causes phase transition of the first chalcogenide material may be smaller than a second threshold voltage that causes phase transition of the second chalcogenide material.

### CROSS-REFERENCE TO RELATED PATENT APPLICATION

This application claims the benefit of Korean Patent Application No. 10-2024-0144774, filed on Oct. 22, 2024, in the Korean Intellectual Property Office, the disclosure of which is incorporated herein in its entirety by reference.

### TECHNICAL FIELD

The present disclosure relates to a semiconductor technology, and more particularly, to a memory element for implementing multi-level on the basis of a chalcogenide material and a memory device including the same.

The present disclosure was derived from research conducted as part of Next-Generation Intelligent Semiconductor Technology Development of the Ministry of Science and ICT (Project Identification No.: 2710006238, Sub-Project No.: 00407199, Research Project Title: Development of Ultra-Low-Power, High-Performance Phase Change Memory/Memristor Device Based on Heterostructure through Heat Diffusion Control, Institute of Organization: Korea University Industry-Academic Cooperation Foundation, Research Period: Mar. 1, 2024 to Dec. 31, 2026).

Meanwhile, in all the aspects of the inventive concept, there is no property interest in the government of the Republic of Korea.

### BACKGROUND

A chalcogenide material is a binary compound semiconductor or more composed of a chalcogen element and is a material that is classified as a semimetal. The chalcogenide material has phase change characteristics and photoelectric conversion characteristics, and based on these characteristics, it is widely used in optical and electrical memories, medical devices, and optical elements. Recently, as the material can be developed on the basis of fast switching characteristics and solution deposition methods, the chalcogenide material has been evaluated as a next-generation source material, and accordingly, various researches using the chalcogenide material are being conducted.

Recently, a memory element in a form that stores information through a resistance change of a material has been proposed in the field of memory. A recently commercialized phase change memory (PCM) is a representative example of a memory that utilizes the characteristics of the chalcogenide material described above. In the PCM, a state may be converted on the basis of heating and cooling generated by current by utilizing the characteristics of the chalcogenide material of which a resistance changes between crystalline and amorphous states. The PCM stores binary information of 0 and 1 by utilizing a difference in electrical conductivity caused by the state change of the chalcogenide material and may be manufactured in an integrated form by disposing a material capable of implementing a resistance state at a contact point between a word line and a bit line.

In this regard, reference may be made to Korean Patent Publication No. 10-2024-0011009A and Korean Patent Publication No. 10-2023-0055240A.

### SUMMARY

### Technical Problem

The present disclosure is directed to providing a memory element for implementing a multi-level cell (MLC) on the basis of a chalcogenide material and a memory device including the same.

The present disclosure is directed to providing a memory element with a structure in which layers formed of the chalcogenide material are vertically stacked and a memory device including the same.

The problems to be solved by the present disclosure are not limited to the above-described problems, and other problems not mentioned will be clearly understood by those having ordinary skill in the art from the description below.

### Technical Solution

A memory element according to an embodiment of the present disclosure may include a lower electrode that includes a heater, a stacked structure that is stacked on the lower electrode and includes a first chalcogenide layer that includes a first chalcogenide material, a second chalcogenide layer that includes a second chalcogenide material, and a first anti-mixing layer that prevents diffusion between the first chalcogenide layer and the second chalcogenide layer, and an upper electrode that is stacked on the stacked structure, wherein the first chalcogenide layer may be stacked on the lower electrode, the first anti-mixing layer may be stacked on the first chalcogenide layer, the second chalcogenide layer may be stacked on the first anti-mixing layer, and a first threshold voltage that causes phase transition of the first chalcogenide material may be smaller than a second threshold voltage that causes phase transition of the second chalcogenide material.

In an embodiment, the stacked structure may further include a third chalcogenide layer that includes a third chalcogenide material and a second anti-mixing layer that prevents diffusion between the second chalcogenide layer and the third chalcogenide layer, wherein the second anti-mixing layer may be stacked on the second chalcogenide layer, the third chalcogenide layer may be stacked on the second anti-mixing layer, and the second threshold voltage may be smaller than a third threshold voltage that causes phase transition of the third chalcogenide material.

In an embodiment, when the first chalcogenide material and the second chalcogenide material are in an amorphous state, the memory element may form a first level corresponding to a first resistance that indicates a high-resistance state.

In an embodiment, when a first pulse voltage equal to or greater than the first threshold voltage and smaller than the second threshold voltage is applied to the stacked structure, the first chalcogenide material may be phase-transitioned into a crystalline state, the memory element may form a second level corresponding to a second resistance based on the phase transition of the first chalcogenide material, and the second resistance may be smaller than the first resistance.

In an embodiment, when a second pulse voltage equal to or greater than the second threshold voltage is applied to the stacked structure, the second chalcogenide material may be phase-transitioned into the crystalline state, the memory element may form a third level corresponding to a third resistance based on the phase transition of the second chalcogenide material, and the third resistance may be smaller than the second resistance.

In an embodiment, when a third pulse voltage is applied to the stacked structure, a first conduction channel may be formed for the first chalcogenide layer, and the memory element may form a fourth level corresponding to a fourth resistance based on the first conduction channel, wherein the third pulse voltage may be equal to or greater than a fourth threshold voltage that is a voltage required to form a conduction channel for the first chalcogenide layer and smaller than a fifth threshold voltage that is a voltage required to form the conduction channel for the second chalcogenide layer, and the fourth resistance may be smaller than the first resistance.

In an embodiment, when a fourth pulse voltage with the same polarity as the first conduction channel formed for the first chalcogenide layer is applied to the stacked structure, the fourth threshold voltage may be shifted from a first voltage to a second voltage, and the second voltage may be smaller than the first voltage.

In an embodiment, the memory element may further include an insulator that surrounds the lower electrode.

A memory device according to an embodiment of the present disclosure may include a memory array formed by arranging a plurality of memory elements in at least one row and at least one column, wherein each of the plurality of memory elements may include a lower electrode that includes a heater, a stacked structure that is stacked on the lower electrode and includes a first chalcogenide layer that includes a first chalcogenide material, a second chalcogenide layer that includes a second chalcogenide material, and a first anti-mixing layer that prevents diffusion between the first chalcogenide layer and the second chalcogenide layer, and an upper electrode that is stacked on the stacked structure, wherein the first chalcogenide layer may be stacked on the lower electrode, the first anti-mixing layer may be stacked on the first chalcogenide layer, the second chalcogenide layer may be stacked on the first anti-mixing layer, and a first threshold voltage that causes phase transition of the first chalcogenide material may be smaller than a second threshold voltage that causes phase transition of the second chalcogenide material.

In a method of implementing multi-level by a memory element that includes a stacked structure in which a plurality of chalcogenide layers are stacked, the method of implementing multi-level may include applying a pulse voltage to the stacked structure and forming a resistance corresponding to phase transition of at least some of the plurality of chalcogenide layers caused by the pulse voltage, wherein the stacked structure may include a first chalcogenide layer that includes a first chalcogenide material, an anti-mixing layer that is stacked on the first chalcogenide layer, and a second chalcogenide layer that is stacked on the anti-mixing layer and includes a second chalcogenide material, and when the pulse voltage is smaller than a first threshold voltage that causes the phase transition of the first chalcogenide material, a first level corresponding to a first resistance may be formed, when the pulse voltage is equal to or greater than the first threshold voltage and smaller than a second threshold voltage that causes phase transition of the second chalcogenide material, a second level corresponding to a second resistance may be formed, when the pulse voltage is equal to or greater than the second threshold voltage, a third level corresponding to a third resistance may be formed, the first threshold voltage may be smaller than the second threshold voltage, the first resistance is greater than the second resistance, and the second resistance may be greater than the third resistance.

### Advantageous Effects

According to the present disclosure, it is possible to secure various resistance states and implement multi-bit driving based on the same by implementing a multi-level cell (MLC) on the basis of a chalcogenide material.

According to the present disclosure, it is possible to implement a memory element through a simple process, and to easily expand a storage space by implementing a high-density memory array based on the memory element.

According to the present disclosure, it is possible to improve durability and reliability of the memory element and the memory device including the same by stacking an anti-mixing layer between layers formed of the chalcogenide material for preventing interference between the layers formed of the chalcogenide material.

The effects according to the present disclosure are not limited to the above-described effects, and other effects not mentioned will be clearly understood by those having ordinary skill in the art from the description below.

### BRIEF DESCRIPTION OF THE DRAWINGS

FIG. 1 is a cross-sectional view of a memory element according to an embodiment of the present disclosure.

FIG. 2 is a view for describing a first characteristic of a chalcogenide layer according to an embodiment of the present disclosure.

FIG. 3 and FIG. 4 are views for describing a method of driving a memory element for implementing multi-level on the basis of the first characteristic of the chalcogenide layer according to an embodiment of the present disclosure.

FIG. 5 is a view for describing a second characteristic of the chalcogenide layer according to an embodiment of the present disclosure.

FIG. 6 and FIG. 7 are views for describing a method of driving a memory element for implementing multi-level on the basis of the second characteristic of the chalcogenide layer according to an embodiment of the present disclosure.

FIG. 8 is a view for describing a third characteristic of the chalcogenide layer according to an embodiment of the present disclosure.

FIG. 9 is a view for describing a method of driving a memory element for implementing multi-level on the basis of the third characteristic of the chalcogenide layer according to an embodiment of the present disclosure.

FIG. 10 is a view for showing a memory device according to an embodiment of the present disclosure.

FIG. 11 is a view for showing an electronic device according to an embodiment of the present disclosure.

### DETAILED DESCRIPTION OF THE EMBODIMENTS

Hereinafter, exemplary embodiments according to the present disclosure will be described in detail with reference to the content described in the attached drawings. However, the present disclosure is not restricted or limited by the exemplary embodiments. Unless otherwise defined, all terms (including technical and scientific terms) used herein are to be used with a meaning commonly understood by those having ordinary skill in the art to which this disclosure pertains, but this may vary depending on the intention of those skilled in the art, case law, or emergence of new technologies, etc.

In addition, terms defined in a commonly used dictionary are not to be interpreted ideally or excessively unless clearly and specifically defined otherwise. In a specific case, there are terms that the applicant has arbitrarily selected, and in this case, their meanings will be described in detail in the corresponding description part. Accordingly, the terms used in herein should be defined based on the meaning of the terms and the overall content of the present disclosure, rather than simply the names of the terms.

When it is said throughout this specification that a part “includes” a certain component, this does not exclude other components unless otherwise stated, but means other components may be further included. In addition, the singular forms used herein also include the plural forms unless specifically stated otherwise. In addition, the expression “at least one of a, b, and/or c” described throughout the present specification may encompass “a alone”, “b alone”, “c alone”, “a and b”, “a and c”, “b and c”, or “all of a, b, and c”.

Meanwhile, terms such as “first and/or second” used herein may be used to describe various components, but they are only used for the purpose of distinguishing one component from another component, and are not intended to be limited to the components referred to by the terms. For example, without departing from the scope of the present disclosure, the first component may be named as the second component, and the second component may also be named as the first component.

Hereinafter, various embodiments of the present disclosure will be described in detail with reference to the attached drawings. In describing the embodiments, a description of technical contents that are well known in the technical field to which the present disclosure pertains and are not directly related to the present disclosure will be omitted. This is to convey the gist of the present disclosure more clearly without obscuring the same by omitting unnecessary explanation. For the same reason, some components in the attached drawings are exaggerated, omitted, or schematically shown. In addition, size of each component does not entirely reflect its actual size. In the present specification, like reference numerals may refer to like or corresponding components throughout.

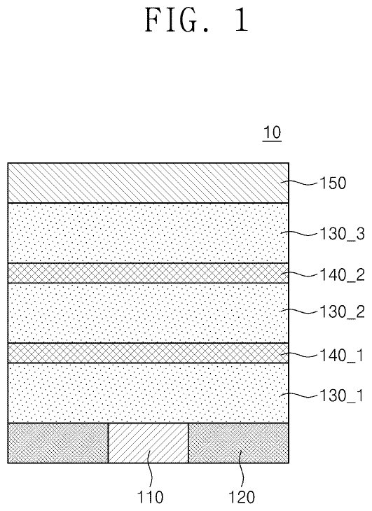

FIG. 1 is a cross-sectional view of a memory element 10 according to an embodiment of the present disclosure.

Referring to FIG. 1, the memory element 10 according to an embodiment of the present disclosure may include a lower electrode 110, an insulator 120, a first chalcogenide layer 130_1, a second chalcogenide layer 130_2, a third chalcogenide layer 130_3, a first anti-mixing layer 140_1, a second anti-mixing layer 140_2, and an upper electrode 150.

According to the embodiment of the present disclosure, the lower electrode 110 may include a heater (e.g., a nano heater), generate thermal energy based on electrical energy supplied to the memory element 10, and transfer the generated thermal energy to the memory element 10. In an embodiment, the lower electrode 110 may include a metal material, and for example, the metal material may include at least one of TiN, Pt, W, TiW, Ag, Ta, TaN, TaW, Al, TiAl, MoN, MoAlN, TaSiN, TaAlN, WON, TiCN, and TiON.

According to the embodiment of the present disclosure, the insulator 120 may be disposed to surround the lower electrode 110 and prevent loss of electrical energy and thermal energy generated from at least one component constituting the memory element 10. For example, the insulator 120 may include at least one of SiO2, Al2O3, TiO2, Ta2O5, HfO, NiO, CoO, MnO, WO, ZrO, RuO, MoO, and FeO.

According to the embodiment of the present disclosure, a plurality of the chalcogenide layers 130_1, 130_2, and 130_3 and a plurality of the anti-mixing layers 140_1 and 140_2 may be stacked on the lower electrode 110 and the insulator 120. Specifically, the first chalcogenide layer 130_1 may be stacked on the lower electrode 110 and the insulator 120, the first anti-mixing layer 140_1 may be stacked on the first chalcogenide layer 130_1, the second chalcogenide layer 130_2 may be stacked on the first anti-mixing layer 140_1, the second anti-mixing layer 140_2 may be stacked on the second chalcogenide layer 130_2, and the third chalcogenide layer 130_3 may be stacked on the second anti-mixing layer 140_2. Hereinafter, in the present specification, a structure in which the chalcogenide layers and the anti-mixing layers are alternately stacked may be referred to as a stacked structure.

In the embodiment, each of the plurality of chalcogenide layers 130_1, 130_2, and 130_3 may include a chalcogenide material, and for example, the chalcogenide material may include at least one of GeTe, GeSe, GeS, GeSbTe, GeSbSe, and GeSbS. According to an embodiment of the present disclosure, type or composition ratio of the material constituting each of the plurality of chalcogenide layers 130_1, 130_2, and 130_3 may be different from each other, and accordingly, a threshold voltage corresponding to each of the plurality of chalcogenide layers 130_1, 130_2, and 130_3 may be different from each other. The threshold voltage may refer to a voltage that causes a difference in electrical conductivity due to a change in a state of the chalcogenide material included in each of the plurality of chalcogenide layers 130_1, 130_2, and 130_3. In an embodiment, the plurality of chalcogenide layers 130_1, 130_2, and 130_3 may be disposed from a lower part of the memory element 10 in order of increasing threshold voltage. Specifically, when a threshold voltage of the first chalcogenide layer 130_1 is V1, a threshold voltage of the second chalcogenide layer 130_2 is V2, and a threshold voltage of the third chalcogenide layer 130_3 is V3, a first threshold voltage may be smaller than a second threshold voltage, and the second threshold voltage may be smaller than a third threshold voltage.

In the embodiment, the threshold voltage of each of the plurality of chalcogenide layers 130_1, 130_2, and 130_3 may correspond to a melting point of each of the plurality of chalcogenide layers 130_1, 130_2, and 130_3. That is, a first melting point of the first chalcogenide layer 130_1 may be lower than a second melting point of the second chalcogenide layer 130_2, and the second melting point of the second chalcogenide layer 130_2 may be lower than a third melting point of the third chalcogenide layer 130_3. In an embodiment, a first temperature may be 100° C. lower than a second temperature, and the second temperature may be 100° C. lower than a third temperature.

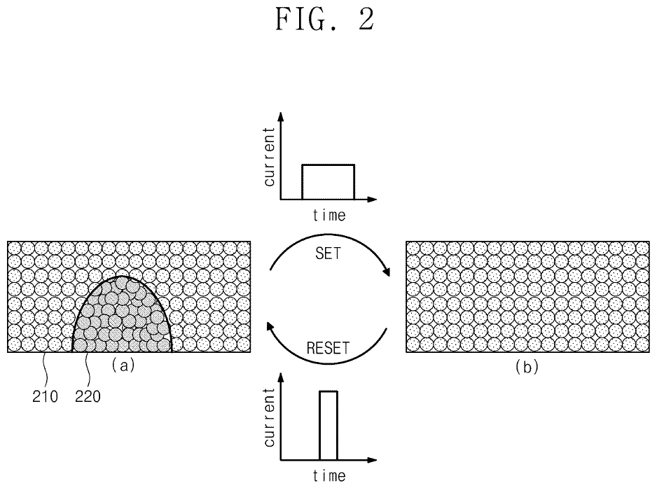

In the embodiment, the state of the chalcogenide material included in each of the plurality of chalcogenide layers 130_1, 130_2, and 130_3 may be changed on the basis of the thermal energy provided from the lower electrode 110. When a voltage is applied to the memory element 10, the state of the chalcogenide material included in the first chalcogenide layer 130_1, which has the lowest melting point and is disposed to be the closest to the lower electrode 110 that supplies heat, may change first. Meanwhile, the state of the chalcogenide material included in the third chalcogenide layer 130_3, which has the highest melting point and is disposed to be closest to the upper electrode 110, may change last. Specific details regarding the state change of each of the plurality of chalcogenide layers 130_1, 130_2, and 130_3 and a multi-level implementation method according to the change will be described in detail with reference to FIGS. 2 to 9 to be described later.

Meanwhile, each of the plurality of anti-mixing layers 140_1 and 140_2 may be disposed between the plurality of chalcogenide layers 130_1, 130_2, and 130_3 to prevent interference (e.g., diffusion of the chalcogenide material, mixing of a conduction channel (or conduction path)) between the plurality of chalcogenide layers 130_1, 130_2, and 130_3. In addition, each of the plurality of anti-mixing layers 140_1 and 140_2 may prevent thermal energy diffusion from each of the plurality of chalcogenide layers 130_1, 130_2, and 130_3. For example, each of the plurality of anti-mixing layers 140_1 and 140_2 may include at least one of SiN and TiN materials. A method of driving the memory element 10 by the stacked structure composed of the plurality of chalcogenide layers 130_1, 130_2, and 130_3 and the plurality of anti-mixing layers 140_1 and 140_2 will be described in detail with reference to FIGS. 2 to 9 to be described later.

According to the embodiment of the present disclosure, the upper electrode 150 may transfer electrical energy supplied from outside to the stacked structure composed of the plurality of chalcogenide layers 130_1, 130_2, and 130_3 and the plurality of anti-mixing layers 140_1 and 140_2. The upper electrode 150 may be stacked on the third chalcogenide layer 130_3 that is disposed at an uppermost end of the stacked structure. In the embodiment, the upper electrode 150 may include a metal material, and for example, the metal material may include at least one of TiN, Pt, W, TiW, Ag, Ta, TaN, TaW, Al, TiAl, MoN, MoAlN, TaSiN, TaAlN, WON, TiCN, and TiON.

In FIG. 1, although it is shown that the memory element 10 according to the embodiment of the present disclosure includes three chalcogenide layers 130_1, 130_2, and 130_3 and two anti-mixing layers 140_1 and 140_2, this is only an embodiment presented for convenience of description and does not limit the configuration of the memory element 10 according to the present disclosure. The memory element 10 according to the present disclosure may include N chalcogenide layers and N-1 anti-mixing layers (N is a natural number equal to or greater than 2), and the N chalcogenide layers may be disposed from the lower part of the memory element 10 in order of increasing threshold voltage (or melting point), and anti-mixing layers may be disposed between the chalcogenide layers. In other words, the chalcogenide layers and the anti-mixing layers may be alternately stacked to form the stacked structure.

The memory element 10 according to the embodiment of the present disclosure may secure various resistance states by implementing a multi-level cell (MLC) on the basis of the chalcogenide material and implement multi-bit driving on the basis of the same. In addition, the memory element 10 according to the embodiment of the present disclosure may be implemented through a simple process and may be used as a component of a memory array. In addition, the stacked structure of the memory element 10 according to the embodiment of the present disclosure may improve durability and reliability of the memory element 10 and a memory device including the same. A principle of implementing the MLC of the memory element 10 according to the embodiment of the present disclosure will be described in detail with reference to FIGS. 2 to 9 to be described below.

FIG. 2 is a view for describing a first characteristic of a chalcogenide layer according to an embodiment of the present disclosure.

According to the embodiment, the chalcogenide material constituting the chalcogenide layer has phase transition characteristics due to joule heating generated when a pulse is applied, and an arrangement state thereof may change based on the thermal energy. Specifically, when the chalcogenide layer includes a first area 210 including a chalcogenide material in a crystalline (regularly arranged) state and a second area 220 including a chalcogenide material in an amorphous (irregularly arranged) state as in (a) of FIG. 2, the chalcogenide material included in the chalcogenide layer may change into the crystalline state when the pulse is applied to the chalcogenide layer including the first area 210 and the second area 220. Meanwhile, when the chalcogenide layer includes the chalcogenide material in the crystalline state as in (b) of FIG. 2, at least some of the chalcogenide material included in the chalcogenide layer may change into the amorphous state. In the embodiment, in order for the state of the chalcogenide material included in the chalcogenide layer to be converted, a voltage equal to or greater than the threshold voltage needs to be supplied to the chalcogenide layer, and the threshold voltage may be determined depending on the material constituting the chalcogenide layer.

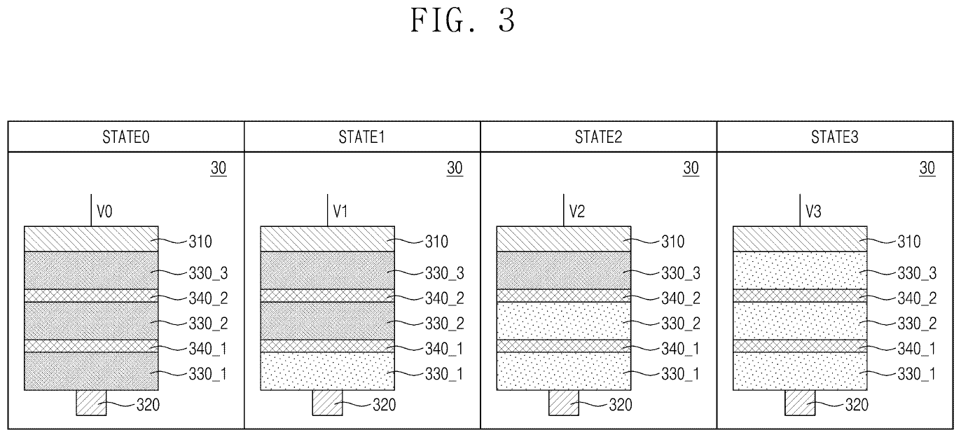

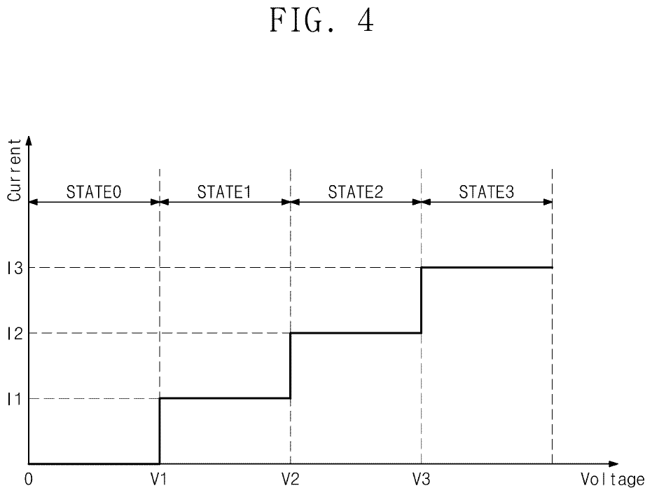

FIG. 3 and FIG. 4 are views for describing a method of driving a memory element 30 for implementing multi-level on the basis of the first characteristic of the chalcogenide layer according to an embodiment of the present disclosure.

Specifically, FIG. 3 shows states that may be implemented for the memory element 30 on the basis of the first characteristic of the chalcogenide layer according to the embodiment of the present disclosure, and components included in the memory element 30 shown in FIG. 3 may correspond to components included in the above-described memory element 10 of FIG. 1 (refer to FIG. 1). Meanwhile, FIG. 4 is a graph showing an amount of current output from the memory element 30 corresponding to a state of the memory element 30 shown in FIG. 3. In FIG. 4, an x-axis may represent a magnitude of a voltage applied to the upper electrode 310, and a y-axis may represent a magnitude of an output current of the memory element 30 for the voltage applied to the upper electrode 310.

Referring to FIG. 3, each of first to third chalcogenide layers 330_1, 330_2, and 330_3 included in the memory element 30 in an initial state (STATE0) according to the embodiment of the present disclosure may include a chalcogenide material in the amorphous state. The chalcogenide material may have characteristics of low optical reflectivity and high electrical resistance in the amorphous state. Assuming that a resistance value formed by the first chalcogenide layer including the chalcogenide material in the amorphous state is R1, a resistance value formed by the second chalcogenide layer including the chalcogenide material in the amorphous state is R2, and a resistance value formed by the third chalcogenide layer including the chalcogenide material in the amorphous state is R3, a resistance value formed by the memory element 30 in the initial state (STATE0) may be R1+R2+R3.

As the chalcogenide material included in each of the first to third chalcogenide layers 330_1, 330_2, and 330_3 is in the amorphous state, the memory element 30 in the initial state (STATE0) may be in a high-resistance state. Even when an initial voltage V0 is applied to the upper electrode 310 of the memory element 30 in the initial state (STATE0) and the initial voltage V0 is smaller than a first threshold voltage V1, the current may not flow depending on the high-resistance state of the memory element 30. In the embodiment, the first threshold voltage V1 may be a voltage required for a state change of the first chalcogenide layer 330_1. In other words, when any initial voltage V0 smaller than the first threshold voltage V1 is applied, an amount of the output current of the memory element 30 in the initial state (STATE0) may be 0[A] as shown in FIG. 4.

Referring to FIG. 3, the memory element 30 in a first state (STATE1) according to the embodiment of the present disclosure may include the first chalcogenide layer 330_1 including the chalcogenide material in the crystalline state, the second chalcogenide layer 330_2 including the chalcogenide material in the amorphous state, and the third chalcogenide layer 330_3 including the chalcogenide material in the amorphous state. The first chalcogenide layer 330_1 including the chalcogenide material in the crystalline state may be formed by applying a voltage equal to or greater than the first threshold voltage V1. The chalcogenide material in the crystalline state may have characteristics of high optical reflectivity and low electrical resistance. Assuming that a resistance value formed by the first chalcogenide layer 330_1 including the chalcogenide material in the crystalline state is R1′, a resistance value formed by the memory element 30 in the first state (STATE1) may be R1′+R2+R3.

As the chalcogenide material in the crystalline state has a characteristic of low electrical resistance, the resistance value R1′ formed by the first chalcogenide layer 330_1 including the chalcogenide material in the crystalline state may be smaller than the resistance value R1 formed by the first chalcogenide layer 330_1 including the chalcogenide material in the amorphous state. Accordingly, the resistance value formed by the memory element 30 in the first state (STATE1) may be smaller than the resistance value formed by the memory element 30 in the initial state (STATE0). As shown in FIG. 4, when any voltage equal to or greater than the first threshold voltage V1 and smaller than a second threshold voltage V2 is applied to the upper electrode 310, an amount of the output current of the memory element 30 in the first state (STATE1) may be I1[A] corresponding to the resistance value formed by the memory element 30. In the embodiment, the second threshold voltage V2 may be a voltage required for a state change of the second chalcogenide layer 330_2.

Referring to FIG. 3, the memory element 30 in a second state (STATE2) according to the embodiment of the present disclosure may include the first chalcogenide layer 330_1 including the chalcogenide material in the crystalline state, the second chalcogenide layer 330_2 including the chalcogenide material in the crystalline state, and the third chalcogenide layer 330_3 including the chalcogenide material in the amorphous state. The second chalcogenide layer 330_2 including the chalcogenide material in the crystalline state may be formed by applying a voltage equal to or greater than the second threshold voltage V2. Assuming that a resistance value formed by the second chalcogenide layer 330_2 including the chalcogenide material in the crystalline state is R2′, a resistance value formed by the memory element 30 in the second state (STATE2) may be R1′+R2′+R3.

The resistance value R2′ formed by the second chalcogenide layer 330_2 including the chalcogenide material in the crystalline state may be smaller than the resistance value R2 formed by the second chalcogenide layer 330_2 including the chalcogenide material in the amorphous state. Accordingly, the resistance value formed by the memory element 30 in the second state (STATE2) may be smaller than the resistance value formed by the memory element 30 in the first state (STATE1). As shown in FIG. 4, when any voltage equal to or greater than the second threshold voltage V2 and smaller than a third threshold voltage V3 is applied to the upper electrode 310, an amount of the output current of the memory element 30 in the second state (STATE2) may be I2[A] corresponding to the resistance value formed by the memory element 30. In the embodiment, the third threshold voltage V3 may be a voltage required for a state change of the third chalcogenide layer 330_3.

The memory element 30 in a third state (STATE3) according to an embodiment of the present disclosure may include the first chalcogenide layer 330_1 including the chalcogenide material in the crystalline state, the second chalcogenide layer 330_2 including the chalcogenide material in the crystalline state, and the third chalcogenide layer 330_3 including the chalcogenide material in the crystalline state. Assuming that a resistance value formed by the third chalcogenide layer 330_3 including the chalcogenide material in the crystalline state is R3′, a resistance value formed by the memory element 30 in the third state (STATE3) may be R1′+R2′+R3′.

The resistance value R3′ formed by the third chalcogenide layer 330_3 including the chalcogenide material in the crystalline state may be smaller than the resistance value R3 formed by the third chalcogenide layer 330_3 including the chalcogenide material in the amorphous state. Accordingly, the resistance value formed by the memory element 30 in the third state (STATE3) may be smaller than the resistance value formed by the memory element 30 in the second state (STATE2). As shown in FIG. 4, when any voltage equal to or greater than the third threshold voltage is applied to the upper electrode 310, an amount of the output current of the memory element 30 in the third state (STATE3) may be I3[A] corresponding to the resistance value formed by the memory element 30.

In the embodiments shown in FIG. 3 and FIG. 4, the memory element 30 may form four resistance values, and the memory element 30 may implement four multi-levels on the basis of the same. Meanwhile, when the memory element 30 includes N chalcogenide layers (N is a natural number equal to or greater than 2), the memory element 30 may implement N+1 multi-levels. According to the embodiment of the present disclosure, multi-level implemented for the memory element 30 on the basis of the first characteristic of the chalcogenide layer may be related to a write operation of the memory device.

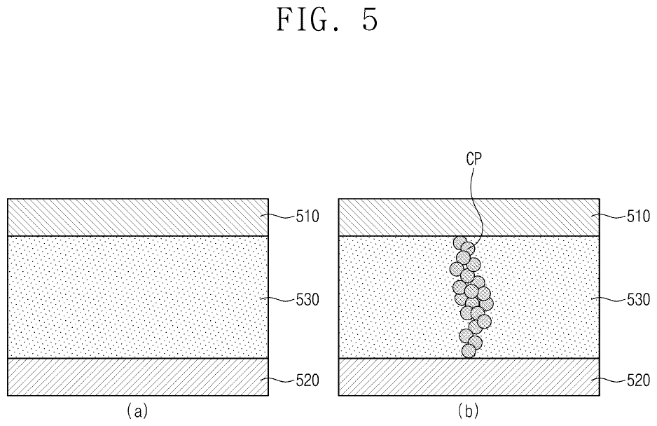

FIG. 5 is a view for describing a second characteristic of the chalcogenide layer according to an embodiment of the present disclosure.

According to an embodiment, Group 16 elements included in the chalcogenide material constituting the chalcogenide layer may have two pairs of unshared electron pairs. The two pairs of unshared electron pairs may exist as defects in the material to form a trap site. When a voltage is applied to the chalcogenide layer, the defects are grouped together, and the grouped defects may form a conduction channel that connects the upper electrode and the lower electrode at a certain voltage, and current may flow to the chalcogenide layer through the conduction channel.

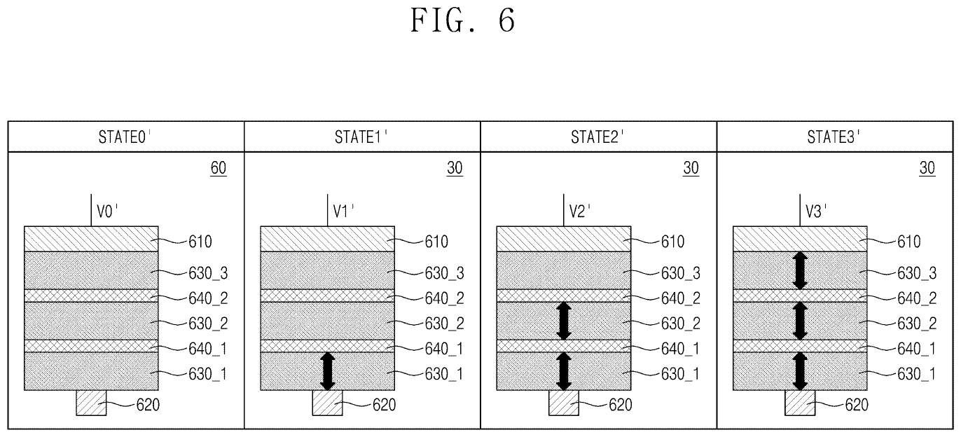

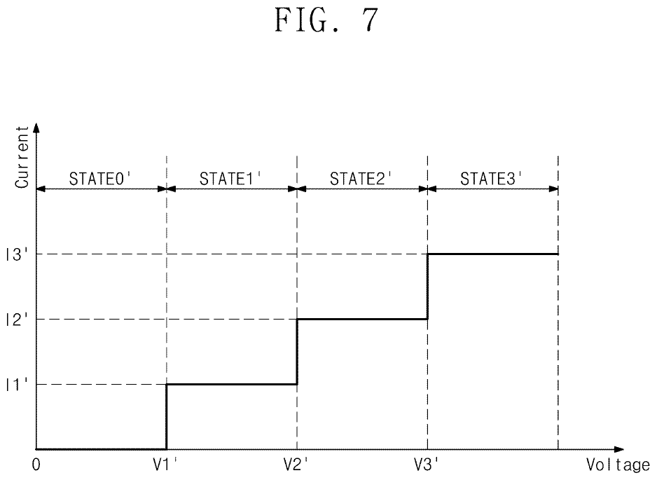

FIG. 6 and FIG. 7 are views for describing a method of driving a memory element 60 for implementing multi-level on the basis of the second characteristic of the chalcogenide layer according to an embodiment of the present disclosure.

Specifically, FIG. 6 shows states that may be implemented for the memory element 60 on the basis of the second characteristic of the chalcogenide layer according to the embodiment of the present disclosure, and components included in the memory element 60 shown in FIG. 6 may correspond to components included in the above-described memory element 10 of FIG. 1 (refer to FIG. 1). Meanwhile, FIG. 7 is a graph showing an amount of current output from the memory element 60 corresponding to a state of the memory element 60 shown in FIG. 6. In FIG. 7, the x-axis may represent a magnitude of a voltage applied to the upper electrode 610, and the y-axis may represent a magnitude of an output current of the memory element 60 for the voltage applied to the upper electrode 310.

FIG. 6 and FIG. 7 show the memory element 60 that implements multi-level on the basis of the second characteristic of the chalcogenide layer for the memory element 30 (refer to FIG. 3 and FIG. 4) in the initial state (STATE0, refer to FIG. 3 and FIG. 4) described in above-described FIG. 3 and FIG. 4, and this is only an embodiment according to the present disclosure and does not limit contents of the present disclosure. According to the present disclosure, it is possible to implement multi-level on the basis of the second characteristic of the chalcogenide layer for each state of the memory element 30 described in above-described FIG. 3 and FIG. 4. Hereinafter, it will be understood that the state of the memory element 60 shown in FIG. 6 and FIG. 7 is unrelated to the state of the memory element 30 shown in FIG. 3 and FIG. 4.

Referring to FIG. 6, each of first to third chalcogenide layers 630_1, 630_2, and 630_3 included in the memory element 60 in an initial state (STATE0) according to the embodiment of the present disclosure may include a chalcogenide material in the amorphous state. The memory element 60 in the initial state (STATE0) shown in FIG. 6 may have high-resistance characteristics as the memory element 30 in the initial state shown in above-described FIG. 3 and FIG. 4. Assuming that a resistance value formed by the first chalcogenide layer 630_1 including the chalcogenide material in the amorphous state is R1, a resistance value formed by the second chalcogenide layer 630_2 including the chalcogenide material in the amorphous state is R2, and a resistance value formed by the third chalcogenide layer 630_3 including the chalcogenide material in the amorphous state is R3, a resistance value formed by the memory element 60 in the initial state (STATE0) may be R1+R2+R3. Accordingly, when any voltage smaller than a first threshold voltage V1′, which is a voltage required to form the conduction channel for the first chalcogenide layer 630_1, is applied to the memory element 60, an amount of the output current of the memory element 60 in the initial state (STATE0) may be 0[A] as shown in FIG. 4.

Referring to FIG. 6, the memory element 60 in the first state (STATE1) according to the embodiment of the present disclosure may include the first chalcogenide layer 630_1 in which a first conduction channel is formed, the second chalcogenide layer 630_2 in which the conduction channel is not formed, and the third chalcogenide layer 630_3 in which the conduction channel is not formed. The first conduction channel may be formed by applying a voltage equal to or greater than the first threshold voltage V1′ to the first chalcogenide layer 630_1. The first chalcogenide layer 630_1 in which the first conduction channel is formed may have a resistance characteristic relatively lower than that of the first chalcogenide layer 630_1 in which the first conduction channel is not formed. Assuming that a resistance value formed by the first chalcogenide layer 630_1 in which the first conduction channel is formed is r1, a resistance value formed by the memory element 60 in the first state (STATE1) may be r1+R2+R3. The resistance value formed by the memory element 60 in the first state (STATE1) may be smaller than the resistance value formed by the memory element 60 in the initial state (STATE0).

As shown in FIG. 7, when any voltage equal to or greater than the first threshold voltage V1′ and smaller than the second threshold voltage V2′ is applied to the upper electrode 610, an amount of the output current of the memory element 60 in the first state (STATE1) may be I1′[A] corresponding to the resistance value formed by the memory element 60. In the embodiment, the second threshold voltage V2′ may be a voltage required to form the conduction channel for the second chalcogenide layer 630_2.

Referring to FIG. 6, the memory element 60 in the second state (STATE2) according to the embodiment of the present disclosure may include the first chalcogenide layer 630_1 in which the first conduction channel is formed, the second chalcogenide layer 630_2 in which a second conduction channel is formed, and the third chalcogenide layer 630_3 in which the conduction channel is not formed. The second conduction channel may be formed by applying a voltage equal to or greater than the second threshold voltage V2′ to the second chalcogenide layer 630_2. The second chalcogenide layer 630_2 in which the second conduction channel is formed may have a resistance characteristic relatively lower than that of the second chalcogenide layer 630_2 in which the second conduction channel is not formed. Assuming that a resistance value formed by the second chalcogenide layer 630_2 in which the second conduction channel is formed is r2, a resistance value formed by the memory element 60 in the second state (STATE2) may be r1+r2+R3. The resistance value formed by the memory element 60 in the second state (STATE2) may be smaller than the resistance value formed by the memory element 60 in the first state (STATE1).

As shown in FIG. 7, when any voltage equal to or greater than the second threshold voltage V2′ and smaller than a third threshold voltage V3′ is applied to the upper electrode 610, an amount of the output current of the memory element 60 in the second state (STATE2) may be I2′[A] corresponding to the resistance value formed by the memory element 60. In the embodiment, the third threshold voltage V3′ may be a voltage required to form the conduction channel for the third chalcogenide layer 630_3.

Referring to FIG. 6, the memory element 60 in the third state (STATE3) according to the embodiment of the present disclosure may include the first chalcogenide layer 630_1 in which the first conduction channel is formed, the second chalcogenide layer 630_2 in which the second conduction channel is formed, and the third chalcogenide layer 630_3 in which a third conduction channel is formed. The third conduction channel may be formed by applying a voltage equal to or greater than the third threshold voltage V3′ to the third chalcogenide layer 630_3. The third chalcogenide layer 630_3 in which the third conduction channel is formed may have a resistance characteristic lower than that of the third chalcogenide layer 630_3 in which the third conduction channel is not formed. Assuming that a resistance value formed by the third chalcogenide layer 630_3 in which the third conduction channel is formed is r3, a resistance value formed by the memory element 60 in the third state (STATE3) may be r1+r2+r3. The resistance value formed by the memory element 60 in the third state (STATE3) may be smaller than the resistance value formed by the memory element 60 in the second state (STATE2).

As shown in FIG. 7, when any voltage equal to or greater than the third threshold voltage V3′ is applied to the upper electrode 610, an amount of the output current of the memory element 60 in the third state (STATE3) may be I3′[A] corresponding to the resistance value formed by the memory element 60.

In the embodiments shown in FIG. 6 and FIG. 7, the memory element 60 may form four resistance values, and the memory element 60 may implement four multi-levels on the basis of the same. Meanwhile, when the memory element 60 includes N chalcogenide layers (N is a natural number equal to or greater than 2), the memory element 60 may implement N+1 multi-levels. According to the embodiment of the present disclosure, multi-level implemented for the memory element 60 on the basis of the second characteristic of the chalcogenide layer may be related to the write operation of the memory device.

Meanwhile, the four multi-levels implemented in the embodiments shown in FIG. 6 and FIG. 7 may be different from the four multi-levels implemented in the embodiments shown in above-described FIG. 3 and FIG. 4, and the multi-levels may be implemented by applying the principle described in FIG. 6 and FIG. 7 to each of the states of the memory element 30 shown in above-described FIG. 3 and FIG. 4. Therefore, the memory element implemented by applying the principle described in FIG. 3, FIG. 4, FIG. 6, and FIG. 7 may implement 16 multi-levels.

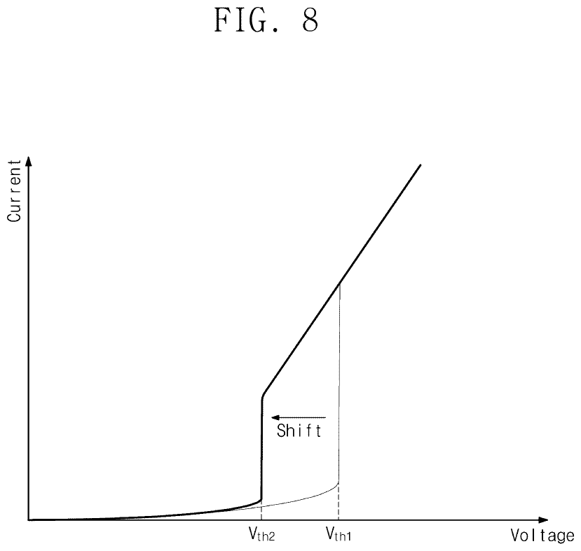

FIG. 8 is a view for describing a third characteristic of the chalcogenide layer according to an embodiment of the present disclosure.

According to an embodiment, the chalcogenide material may have a pattern in which the electrical conductivity changes sharply at a specific threshold voltage. Referring to FIG. 8, the electrical conductivity of the chalcogenide material in the initial state may change sharply at a first threshold voltage Vₜₕ₁. Meanwhile, when a pulse with the same polarity is applied to a conduction channel generated by applying a voltage to the chalcogenide material, the conduction channel may be partially maintained, and accordingly, the threshold voltage may decrease. Referring to FIG. 8, when a pulse with the same polarity is applied to a conduction channel generated for the chalcogenide material in the initial state, the threshold voltage may be shifted to a second threshold voltage Vₜₕ₂. Although not shown, when a pulse with opposite polarity is applied to the conduction channel generated for the chalcogenide material, the defects forming the conduction channel may break bonds and rearrange in an opposite direction, and thus the threshold voltage may increase.

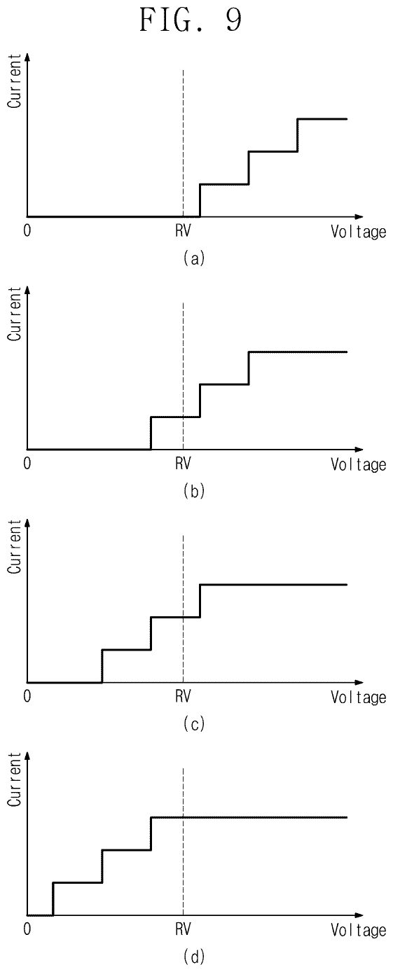

FIG. 9 is a view for describing a method of driving a memory element for implementing multi-level on the basis of the third characteristic of the chalcogenide layer according to an embodiment of the present disclosure.

In an embodiment, the third characteristic of the above-described chalcogenide layer through FIG. 8 may be related to a read operation for multi-level of the memory element. Referring to FIG. 9, (a) shows an amount of current derived from the memory element in the initial state in which no voltage shift occurred, and a level indicated by the memory element may be confirmed through application of a read voltage RV. In state (a) of FIG. 9, a first level indicated by the memory element may be confirmed according to the application of the read voltage RV.

In FIG. 9, (b) shows an amount of current derived from the memory element when a pulse voltage with the same polarity as that of the conduction channel formed in the chalcogenide layer included in the memory element in the initial state is applied. A threshold voltage shift may occur for the chalcogenide layer in which the conduction channel is partially maintained according to the application of the pulse voltage, and the level indicated by the memory element may be confirmed through the application of the read voltage RV. In state (b) of FIG. 9, a second level indicated by the memory element may be confirmed according to the application of the read voltage RV.

In FIG. 9, (c) shows an amount of current derived from the memory element when the pulse voltage with the same polarity as that of the conduction channel formed in the chalcogenide layer is applied again to the memory element in state (b). The threshold voltage shift may occur again for the chalcogenide layer in which the conduction channel is partially maintained according to the application of the pulse voltage, and the level indicated by the memory element may be confirmed through the application of the read voltage RV. In state (c) of FIG. 9, a third level indicated by the memory element may be confirmed according to the application of the read voltage RV.

In FIG. 9, (d) shows an amount of current derived from the memory element when the pulse voltage with the same polarity as that of the conduction channel formed in the chalcogenide layer is applied again to the memory element in state (c). The threshold voltage shift may occur again for the chalcogenide layer in which the conduction channel is partially maintained according to the application of the pulse voltage, and the level indicated by the memory element may be confirmed through the application of the read voltage RV. In state (d) of FIG. 9, a fourth level indicated by the memory element may be confirmed according to the application of the read voltage RV.

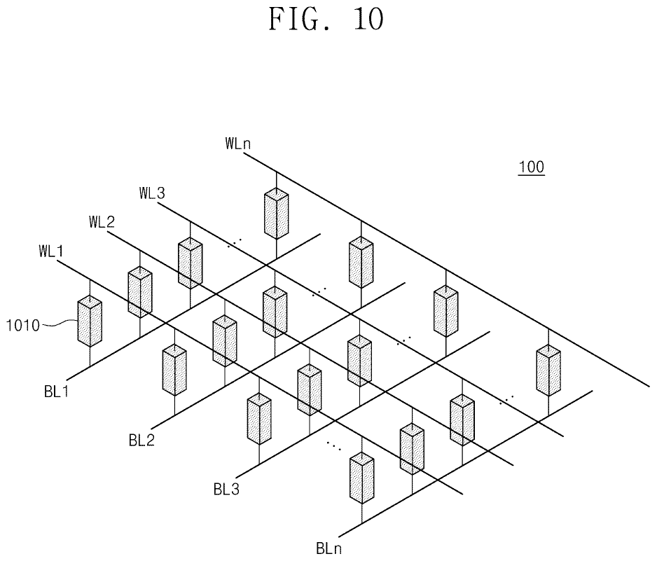

FIG. 10 is a view for showing a memory device 100 according to an embodiment of the present disclosure.

Referring to FIG. 10, the memory device 100 according to the embodiment of the present disclosure may include a plurality of memory elements 810, a plurality of word lines (WL1, WL2, . . . , WLn), and a plurality of bit lines (BL1, BL2, . . . , BLn) (n is a natural number). Each of the plurality of memory elements 810 shown in FIG. 10 may correspond to the memory element 10 shown in above-described FIG. 1 (refer to FIG. 1). The memory device 100 according to an embodiment may be a memory chip and may be used to temporarily or permanently store data in an electronic device. In the embodiment, each of the plurality of word lines (WL1, WL2, . . . , WLn) is for supplying a signal for selecting a memory cell (corresponding to each of the plurality of memory elements 810), and the memory device 100 may process on/off switching of the memory cell on the basis of a signal supplied to the word lines. In the embodiment, each of the plurality of bit lines (BL1, BL2, . . . , BLn) is for sharing a charge stored in the memory cell, and the memory device 100 may read and write data through the bit lines.

According to the embodiment of the present disclosure, the plurality of memory elements 810 may be arranged in at least one row and at least one column to form a memory array. Each of the plurality of memory elements 810 may implement multi-level according to the principle described through above-described FIGS. 2 to 9. Meanwhile, the word line may be connected to the upper electrode 150 (refer to FIG. 1) included in each of the plurality of memory elements 810, and the plurality of memory elements 810 arranged in the same row may be connected to the same word line. Specifically, the plurality of memory elements 810 arranged in a first row may be connected to a first word line (WL1). In addition, the bit line may be connected to the lower electrode 110 (refer to FIG. 1) included in each of the plurality of memory elements 810, and the plurality of memory elements 810 arranged in the same column may be connected to the same bit line. Specifically, the plurality of memory elements 810 arranged in a first column may be connected to a first bit line (BL1).

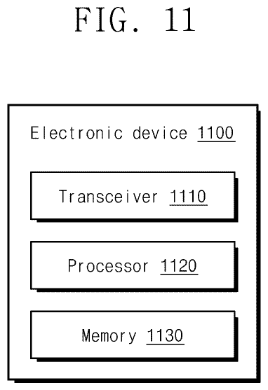

FIG. 11 is a view for showing an electronic device 1100 according to an embodiment of the present disclosure.

Referring to FIG. 11, the electronic device 1100 according to the embodiment of the present disclosure may include a transceiver 1110, a processor 1120, and a memory 1130.

The electronic device 1100 may be connected to an external device through the transceiver 1110 to exchange data. For example, the electronic device 800 may be connected to a streamer terminal 130 (refer to FIG. 1) through the transceiver 810.

The processor 1120 may perform at least one operation performed by the electronic device 1100 or execute a program for performing at least one operation performed by the electronic device 1100. The processor 1120 may process information for performing at least one operation performed by the electronic device 1100 and control the electronic device 1100.

The memory 1130 may store information for performing at least one operation performed by the electronic device 1100. In addition, the memory 1130 may store a code of the program executed by the processor 1120. The memory 1130 may be a volatile memory or a non-volatile memory. In the embodiment, the memory 1130 may include the memory device 100 (refer to FIG. 10) as shown in above-described FIG. 10. As described in FIG. 10, the memory device 100 according to the embodiment of the present disclosure may include a plurality of the memory elements 10 (refer to FIG. 1) arranged in at least one row and at least one column, and each of the plurality of memory elements 10 may implement multi-level for processing information by the electronic device 1100.

The above-described contents are specific embodiments for practicing the present disclosure. The present disclosure will include not only the above-described embodiments, but also embodiments that are simply designed or can be easily changed. In addition, the present disclosure will also include techniques that can be easily modified and implemented using the above-described embodiments. Therefore, the scope of the present disclosure should not be limited to the above-described embodiments, but should be defined not only by the claims described below but also by equivalents of the claims of the present disclosure.

What is claimed is:

1. A memory element comprising:
a lower electrode that includes a heater;
a stacked structure that is stacked on the lower electrode and includes a first chalcogenide layer that includes a first chalcogenide material, a second chalcogenide layer that includes a second chalcogenide material, and a first anti-mixing layer that prevents diffusion between the first chalcogenide layer and the second chalcogenide layer; and
an upper electrode that is stacked on the stacked structure,
wherein the first chalcogenide layer is stacked on the lower electrode, the first anti-mixing layer is stacked on the first chalcogenide layer, the second chalcogenide layer is stacked on the first anti-mixing layer, and a first threshold voltage that causes phase transition of the first chalcogenide material is smaller than a second threshold voltage that causes phase transition of the second chalcogenide material.

2. The memory element of claim 1, wherein the stacked structure further comprises a third chalcogenide layer that includes a third chalcogenide material and a second anti-mixing layer that prevents diffusion between the second chalcogenide layer and the third chalcogenide layer,
wherein the second anti-mixing layer is stacked on the second chalcogenide layer, the third chalcogenide layer is stacked on the second anti-mixing layer, and the second threshold voltage is smaller than a third threshold voltage that causes phase transition of the third chalcogenide material.

3. The memory element of claim 1, wherein, when the first chalcogenide material and the second chalcogenide material are in an amorphous state, a first level corresponding to a first resistance that indicates a high-resistance state is formed.

4. The memory element of claim 3, wherein, when a first pulse voltage equal to or greater than the first threshold voltage and smaller than the second threshold voltage is applied to the stacked structure, the first chalcogenide material is phase-transitioned into a crystalline state, the memory element forms a second level corresponding to a second resistance based on the phase transition of the first chalcogenide material, and the second resistance is smaller than the first resistance.

5. The memory element of claim 4, wherein, when a second pulse voltage equal to or greater than the second threshold voltage is applied to the stacked structure, the second chalcogenide material is phase-transitioned into the crystalline state, the memory element forms a third level corresponding to a third resistance based on the phase transition of the second chalcogenide material, and the third resistance is smaller than the second resistance.

6. The memory element of claim 3, wherein, when a third pulse voltage is applied to the stacked structure, a first conduction channel is formed for the first chalcogenide layer, and the memory element forms a fourth level corresponding to a fourth resistance based on the first conduction channel,
wherein the third pulse voltage is equal to or greater than a fourth threshold voltage that is a voltage required to form a conduction channel for the first chalcogenide layer and is smaller than a fifth threshold voltage that is a voltage required to form the conduction channel for the second chalcogenide layer, and the fourth resistance is smaller than the first resistance.

7. The memory element of claim 6, wherein, when a fourth pulse voltage with the same polarity as the first conduction channel formed for the first chalcogenide layer is applied to the stacked structure, the fourth threshold voltage is shifted from a first voltage to a second voltage, and the second voltage is smaller than the first voltage.

8. The memory element of claim 1, further comprising an insulator that surrounds the lower electrode.

9. A memory device comprising a memory array formed by arranging a plurality of memory elements in at least one row and at least one column, wherein each of the plurality of memory elements includes:
a lower electrode that includes a heater;
a stacked structure that is stacked on the lower electrode and includes a first chalcogenide layer that includes a first chalcogenide material, a second chalcogenide layer that includes a second chalcogenide material, and a first anti-mixing layer that prevents diffusion between the first chalcogenide layer and the second chalcogenide layer; and
an upper electrode that is stacked on the stacked structure,
wherein the first chalcogenide layer is stacked on the lower electrode, the first anti-mixing layer is stacked on the first chalcogenide layer, the second chalcogenide layer is stacked on the first anti-mixing layer, and a first threshold voltage that causes phase transition of the first chalcogenide material is smaller than a second threshold voltage that causes phase transition of the second chalcogenide material.

10. A method of implementing multi-level by a memory element that includes a stacked structure in which a plurality of chalcogenide layers are stacked, the method comprising:
applying a pulse voltage to the stacked structure; and
forming a resistance corresponding to phase transition of at least some of the plurality of chalcogenide layers caused by the pulse voltage,
wherein the stacked structure includes:
a first chalcogenide layer that includes a first chalcogenide material;
an anti-mixing layer that is stacked on the first chalcogenide layer; and
a second chalcogenide layer that is stacked on the anti-mixing layer and includes a second chalcogenide material,
when the pulse voltage is smaller than a first threshold voltage that causes the phase transition of the first chalcogenide material, a first level corresponding to a first resistance is formed, when the pulse voltage is equal to or greater than the first threshold voltage and smaller than a second threshold voltage that causes phase transition of the second chalcogenide material, a second level corresponding to a second resistance is formed, when the pulse voltage is equal to or greater than the second threshold voltage, a third level corresponding to a third resistance is formed, the first threshold voltage is smaller than the second threshold voltage, the first resistance is greater than the second resistance, and the second resistance is greater than the third resistance.
